(19) United States
(12) Patent Application Publication
(10) Pub. No.: US 2012/0199065 A1
(43) Pub. Date: Aug. 9, 2012

(54) Multi-Module System for Processing Thin Film Photovoltaic Devices

(75) Inventors: Robert D. Wieting, Simi Valley, CA (US); Kenneth B. Doering, San Jose, CA (US)

(73) Assignee: Stion Corporation, San Jose, CA (US)

(21) Appl. No.: 13/363,967

(22) Filed: Feb. 1, 2012

Related U.S. Application Data
(60) Provisional application No. 61/439,727, filed on Feb. 4, 2011.

(51) Int. Cl. C23C 16/458; C23C 16/46; C23C 16/52

(52) U.S. Cl. 118/704; 118/719; 118/696

(57) ABSTRACT

A system for in-line substrate processing includes a horizontal rail structure at a first height. A substrate transfer module next to the rail structure receives substrates ready for processing and delivers substrates after processing. Process modules disposed along the rail structure enable process operations on the substrates. A substrate loader moves along the rail structure and transfers substrates to and from the substrate transfer module and to and from the process modules. A controller manages operation of the system.

### CROSS-REFERENCE TO RELATED APPLICATION

This application claims priority to U.S. Provisional Patent Application No. 61/439,727, filed Feb. 4, 2011, commonly assigned, and hereby incorporated by reference in its entirety herein for all purpose.

### BACKGROUND OF THE INVENTION

The present invention relates generally to thin-film photovoltaic techniques. More particularly, the present invention provides a large scale multi-module system for manufacturing thin film photovoltaic devices. Merely by example, embodiments of the present invention are applied to implement a multi-module metal-organic chemical vapor deposition (MOCVD) system for processing thin film photovoltaic devices on large scale substrate panels.

In the process of manufacturing new generations of thin film photovoltaic devices, there are various manufacturing challenges, including scaling up the in-line manufacturing to produce large substrate panels while maintaining structure integrity of substrate material, ensuring uniformity and granularity of the thin film materials, etc. While conventional techniques have addressed some of these issues, they are often inadequate in various situations. Therefore, it is desirable to have an improved multi-module in-line system and method for manufacturing thin film photovoltaic devices.

### BRIEF SUMMARY OF THE INVENTION

According to an embodiment, the present invention provides a multi-module system for fabricating thin film photovoltaic devices. The system includes a rail structure laid out horizontally in a first height extending from a first end region to a second end region. The system further includes a first in-line transfer structure and a second in-line transfer structure disposed at positions next to the first end region. The first in-line transfer structure is configured to supply and store substrates to be processed, while the second in-line transfer structure is configured to store and deliver the plurality of substrates after processing. The system includes a plurality of process modules disposed substantially at the first height along the length of both sides of the rail structure. Furthermore, the system includes a substrate loader coupled to the rail structure and configured to move from the first end region to the second end region along the rail structure and to load substrates from the first in-line transfer structure and unload to the process modules along the sides of the rail structure. It also loads substrates from each process module after processing and unloads them to the second in-line transfer structure. The system includes a controller coupled to the substrate loader, each of the plurality of process modules, and both of the first in-line transfer structure and the second in-line transfer structure. The controller manages a loading/unloading routine of the substrate loader based on a process requirements and any required time delay necessitated by the process modules.

This invention provides numerous benefits over conventional techniques. A multi-module system is provided for large scale in-line processing of thin-film photovoltaic devices on large glass substrates. The system is compatible with well established individual module performance. Each process module comprises an improved metal-organic chemical vapor deposition (MOCVD) chamber for forming conductive oxide thin-film on CIS/CIGS based photovoltaic devices. The module level multiplication of the system is well proved and controlled for each process module to process large substrates having dimension of about 165 cm or greater with substantial uniformity. Further, the system enhances productivity and reduces cost of the in-line processing for large scale manufacture of thin-film photovoltaic devices. The system is controlled by a controller to schedule processing of the substrates.

### BRIEF DESCRIPTION OF THE DRAWINGS

FIG. 1 is a top view of a multi-module system for processing thin-film photovoltaic devices according to an embodiment of the present invention.

FIG. 2 is a perspective view of the multi-module system for processing thin-film photovoltaic devices according to an embodiment of the present invention.

FIG. 3 is a side view of a multi-module system with a controller according to an embodiment of the present invention.

FIG. 4A is a top view of a multi-module system for processing thin-film photovoltaic devices according to another embodiment of the present invention.

FIG. 4B and FIG. 4C is are side views of the multi-module system in FIG. 4A from different view angles according to the embodiment of the present invention.

### DETAILED DESCRIPTION OF THE INVENTION

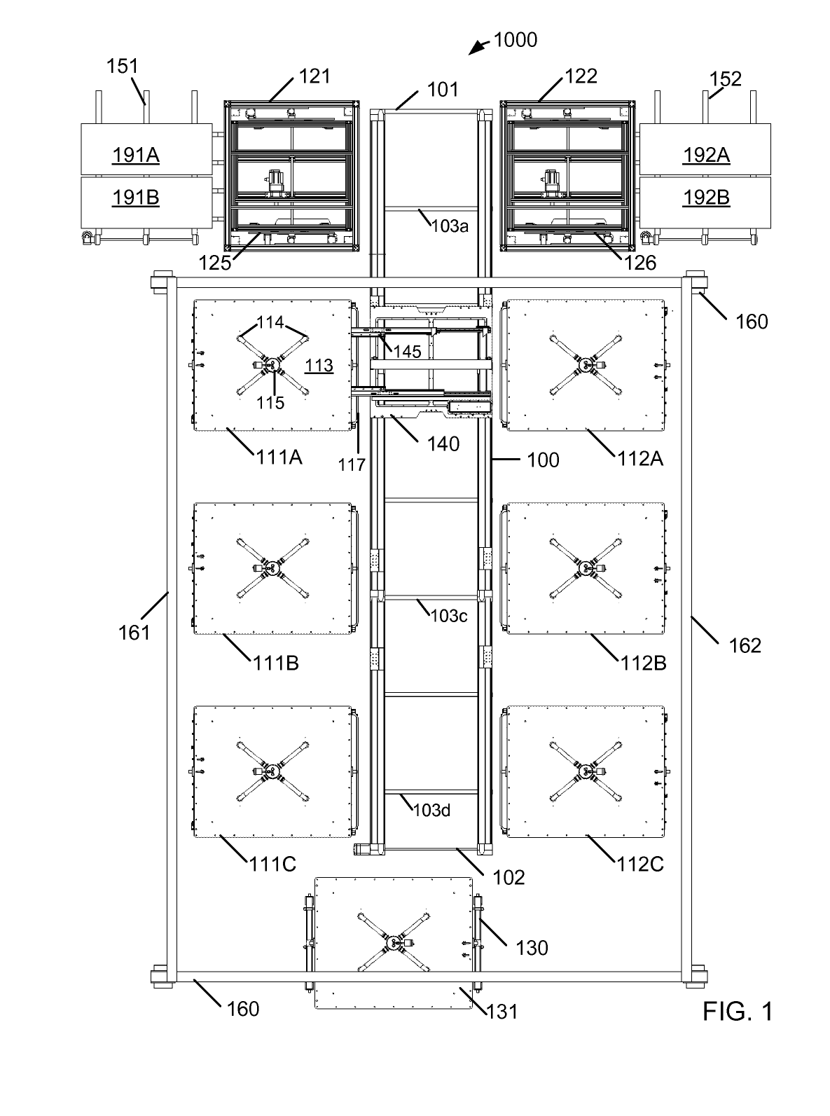

FIG. 1 is a top view of a multi-module system for processing thin-film photovoltaic devices according to an embodiment of the present invention. As shown, a multi-module system 1000 is provided as an in-line station for processing thin film photovoltaic devices formed on large substrate panels. The system 1000 includes a plurality of process modules 111 and 112 respectively disposed along two length sides of a rail structure 100. Two in-line transfer structures 121 and 122 respectively serve as substrate transfer stations, one is for receiving one or more substrates 191 ready for processing from an in-coming substrate transfer line 151 and one is for delivering one or more substrates 192 after processing to an outgoing substrate transfer line 152. Respectively, the two in-line transfer structure 121 and 122 include a loader 125 or 126 to receive the incoming one or more substrates from incoming transfer line 151 or delivering one or more substrates to outgoing transfer line 152. In an embodiment, the two in-line transfer structures 121 and 122 are respectively disposed on opposite sides near a first end region 101 of the rail structure 100. In alternative embodiments, the two rack structures can be both disposed next to the first end region 101. In another embodiment, the system 1000 includes a substrate loader 140 coupled to the rail structure 100. The substrate loader 140 is configured to move along the length of the rail structure 100 from the first end region 101 toward a second end region 102. In a specific embodiment, the rail structure 100 includes a plurality of sections where the substrate loader 140 can stop at corresponding positions 103a, 103c, and 103d to perform loading/unloading functions (currently the substrate loader is shown to be at position 103b). The substrate loader 140 utilizes a robot arm 145 to perform substrate pick-up or unloading from/to either side of the rail structure 100.

In a specific embodiment, each of the plurality of process modules is a deposition chamber configured to perform metal-organic chemical vapor deposition (MOCVD) on one or more substrates loaded therein via the substrate loader 140. As shown in FIG. 1, there are three deposition chambers 111A, 111B, and 111C disposed on one side along the length of the rail structure 100 and there are three other deposition chambers 112A, 112B, and 112C disposed on another side. For simplification of a design of the rail structure 100, each stop position of the substrate loader 140 correspondingly is utilized for serving two deposition chambers on opposite sides of the rail structure 100. For example, deposition chamber 111A is disposed face to face with deposition chamber 112A, although this configuration is merely an example.

In the top view as shown, each deposition chamber has a substantial rectangular shape designed to process a pair of substrates in rectangular form. For example, a pair of substrates 191A and 191B disposed side-by-side on the transfer line (see FIG. 1) can be loaded onto the substrate loader 140 and further into the deposition chamber in the same configuration. In a specific embodiment, each substrate comprises one or more thin-film materials designated for fabricating a photovoltaic device on a large glass panel. In an example, the glass panel is a soda lime glass having a rectangular form factor of 65×165 cm or greater. The thin-film materials on the glass substrate comprise copper indium gallium diselenide (CIGS, or CIS) photovoltaic absorber material overlying one or more electrode material and barrier material formed via other thin-film processes. Each deposition chamber 111 has a top lid cover member 113 coupled with a gas mixing device 115 and four gas inlets 114 for providing work gases required for performing MOCVD process to form a metal oxide material overlying the thin-film materials on the pair of substrates. A pair of substrates is processed in a side-by-side loading configuration provides certain symmetrical advantages to achieve an enhanced thermal uniformity and device quality over the large sized substrates. For more detail about MOCVD processing see U.S. Patent Application No. 61/318,750, entitled “LARGE SCALE MOCVD SYSTEM FOR THIN FILM PHOTOVOLTAIC DEVICES,” filed on Mar. 29, 2010, commonly assigned and incorporated by reference for all purposes.

In another specific embodiment, the system 1000 also includes a crane structure 160 disposed around the plurality of process modules. As shown in FIG. 1, the top view diagram illustrates a frame structure have two frame members 161 and 162 in parallel to the rail structure 100. Not shown in the figure, a lifting tool can be supported by the two frame members 161 and 162 and configured to move along with for lifting any parts of the plurality of process modules. Due to the special large size of the substrates and each corresponding process module, many parts of the process modules may be quite heavy and need the crane structure 160 to lift up. The crane structure 160 can immediately handle and replace the parts when necessary to reduce system down time. The system 1000 has a designated maintenance station 130 to receive the lifted parts by the crane structure. The maintenance station 130 is disposed in a vicinity of the second end region 102 of the rail structure 100 and within the scope of the frame of the crane structure 160. For example shown in FIG. 1, a lid cover member 131 of a deposition chamber has been (lifted out from one deposition chamber and transferred over by the crane structure) placed over the maintenance station 130 for cleaning or repairing works.

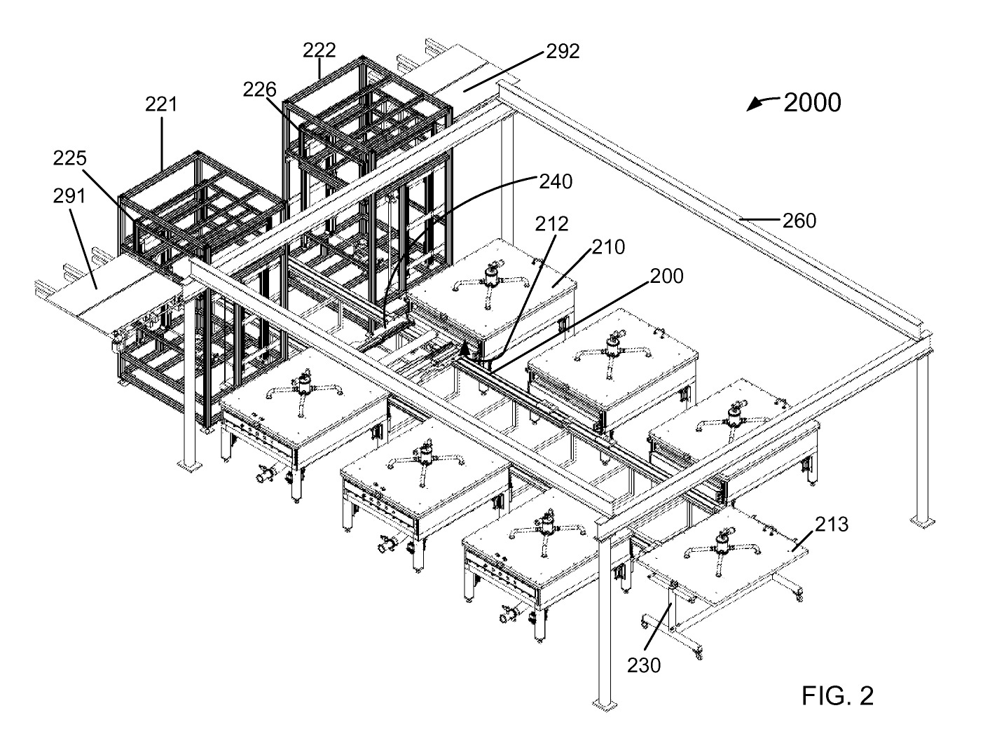

FIG. 2 is a perspective view of the multi-module system for processing thin-film photovoltaic devices according to an embodiment of the present invention. As shown, the multi-module system 2000 is a substantially the system 1000 viewed from an upper left position. A rail structure 200 is laid out in the middle and sided along its length by two rows of multiple process modules 210. Also sided with the rail structure 200, there are two in-line transfer structures 221 and 222 served as substrate transfer stations. Station 221 is connected to an incoming transfer line for receiving new substrates 291 and station 222 is coupled to an outgoing transfer line for delivering substrates 292, after which are processed in the system 2000. In a specific embodiment, each of the two in-line transfer stations 221 and 222 is an elevator structure configured to perform substrate transfer between a first height level designed for processing the substrates in the multiple process modules and a second height level used for substrate transfer lines in the factory. In an implementation, the first height level may be work bench level easy for floor level accessibility and the second height level may be higher (than typical human height) than the first height level for efficient factor space utilization. The elevator structures 221/222 each includes a substrate cart 225/226 configured to load one or more substrates and move up and down to transfer the one or more substrates. In a specific embodiment, the substrate cart 225/226 can be configured to have multiple loading levels and each level may allow a pair of substrates 291/292 to be loaded. A substrate loader 240 coupled to the rail structure 200 can move along the rail structure from one stop position to another and pick up substrates from the substrate cart 225 and deliver to one of the multiple process modules 210 or reload the substrates after processing and send back to the substrate cart 226.

As seen in FIG. 2, each process module 210 is arranged such that a door structure 212 formed in one side member of the process module directly faces the substrate loader 240 on the rail structure 200. Through the side door structure 212, one or more substrates can be loaded/unloaded by the substrate loader 240. The substrate loader 240 is configured to perform loading/unloading operation to process modules disposed at either side of the rail structure 200. Similarly, the substrate loader 240 is configured to pick up or return one or more substrates from or back to the substrate cart 225 or 226 of the rack structure 221 or 222 disposed at either side of the rail structure. Of course, the rack structure including the elevator structure can also be disposed side-by-side near the end of the rail structure and the substrate loader 240 can then be configured to pick up or return substrates from/to the same side of the rail structure. In an alternative embodiment, the substrate loader 240 can be designed with doubled width so that it can pick up ready-for-processing substrates from substrate cart 225 and return after-processing substrates back to substrate cart 226 at the same time. In a specific embodiment, the substrate loader (and the substrate cart or at least one loading level of the substrate cart as well) is configured to hold a pair of rectangular substrates in a side-by-side configuration. Correspondingly, each process module also is configured to hold the pair of substrates in the side-by-side configuration horizontally disposed inside a deposition chamber during processing time. In an implementation, a pair of 65 cm×165 cm rectangular glass substrate panels can be loaded side-by-side into the process module 210 through the door structure 212.

In another embodiment, the system 2000 has a framed crane structure 260 disposed above the multiple process modules 210. The crane structure 260 is designed to lift heavy module parts when they need to be replaced or repaired or need any other maintenance works. In yet another embodiment, the system 2000 includes a maintenance station 230 where a module part 213 can be supported for relevant maintenance works. The module part 213 can be directly transferred by the crane structure 260 from any one of the multiple process modules 210. Within the maintenance station 213, the module part can be flipped back and forth for handling convenience. In an embodiment, the maintenance station is a mobile station for additional handling convenience.

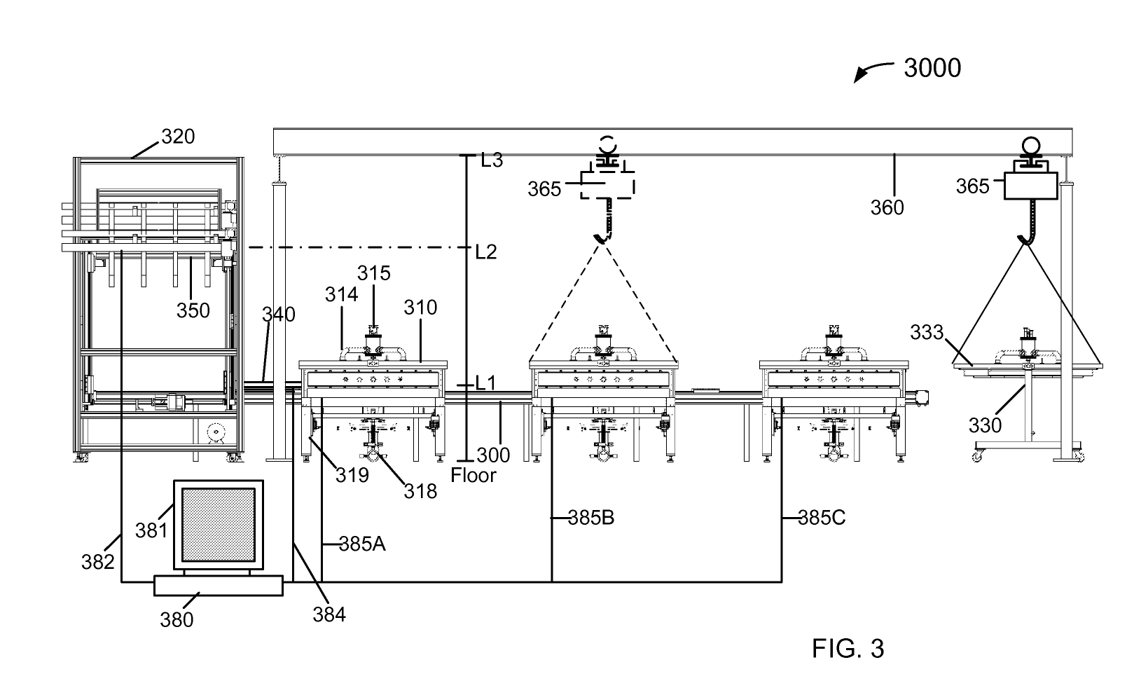

FIG. 3 is a side view of a multi-module system with a controller according to an embodiment of the present invention. As shown, the multi-module system 3000 is laid out on a floor of a factory for processing a plurality of thin-film photovoltaic devices on large substrates in an in-line processing configuration with multiple operation schedules set by a controller. In an embodiment, the multi-module system 3000 is substantially the same as the system 1000 or system 2000 or the likes described earlier. Accordingly, the system 3000 includes at least an in-line transfer structure 320 to couple with a substrate transfer line for receiving or delivering substrates. The system 3000 also includes a rail structure 300 laid out horizontally to associate the in-line transfer structure 320 with a plurality of process modules 310 along a length of the rail structure 300. A substrate loader 340 is movably coupled with the rail structure 300 from one position to another to access the in-line transfer structure 320 and each of the process modules 310 for transferring one or more substrates for in-line processing.

In a specific embodiment, the system 3000 includes a controller 380 coupled respectively to the in-line transfer structure 320, the substrate loader 340, and each of the process modules 310 for receiving operation status data from a plurality of sensors placed on those system elements and sending operation commands to operate the substrate loader 340 for executing loading/unloading works following a predetermined time schedule. In a specific embodiment, the controller controls the in-line transfer structure 320 and its operation associated with the in-coming substrate supply and outgoing substrate delivery. The in-line transfer structure 320 includes a multi-level substrate cart for holding extra number of substrates to provide certain buffers for the in-line substrate processing via the system's plurality of process modules. In another specific embodiment, a controller may be provided in connection with a predetermined consecutive time delay to operate the plurality of process modules one after another to accommodate substrate the process time within each process module and loading/unloading time by the substrate loader between the in-line transfer structure and each corresponding process module. For example, the controller sets an operation schedule for each of the plurality of process modules to start a process sequentially with a predetermined time delay and correspondingly within the predetermined time delay for the substrate loader to obtain a pair of substrates from the first in-line transfer structure, to deliver to a corresponding process module, to pick up another pair of substrates processed in another process module, and to deliver back to the second in-line transfer structure.

In an embodiment, a controller 380 is formed from components that include an interface module 381 and a control module 380 with I/O local bus links 382, 384, 385A, 385B, and 385C respectively for controlling in-line substrate transfer, substrate loading/unloading, and multiple process modules. The interface module 381 may receive inputs from local or remote sources regarding the in-line system operation. In a specific embodiment, controller 380 receives input data from a plurality of sensors placed on all relevant elements of the multi-module system 3000. The sensors (not shown) correspond to any equipment that ascertains the in-line processing operation of the plurality of substrates. These may include, for example, timers, motion sensors, temperature sensors, pressure sensors, gauges, meters, optical detectors, image sensors, and other equipments. As described with other embodiments, a local bus may connect the controller 380 to the sensors to receive the input data in real-time, or as feedback to control implementations.

In a specific embodiment, the controller 380, or portions thereof, is implemented in the form of a dedicated device that is mounted or otherwise placed in position to receive on-site input/feedback information. Thus, for example, the controller 380 may be implemented in the form of a box, through hardware, firmware or software that directly communicates with, for example, all sensors and other equipment. In another specific embodiment, however, the controller 380 may be implemented on a computer, such as on a personal computer (desktop machine, laptop, small-form factor device, etc.) or a microprocessor. Still further, the controller 380 may be distributed over multiple machines or devices, and/or at multiple locations.

Referring to FIG. 3, the system 3000 also includes a crane structure 360 disposed over the plurality of process modules 310 along the length of the rail structure 300. In an implementation of the system for processing thin-film photovoltaic devices on large glass substrates, due to extra large form factor of the substrates processed by the system 3000, the process modules are also made by components or parts with large size and heavy weight. The crane structure 360 includes a framed body located at a height L3 over the floor. A lifting module 365 is movably coupled with the frame body and used for lifting any module part from its installed position to a maintenance station 330. For example, a lid cover member 313 of a process module has been transferred to the maintenance station 330 as shown in FIG. 3.

Also seen in FIG. 3, two other height levels are marked. L1 is used to indicate a first height level for the rail structure laid out horizontally on a floor. The height L1 is about a nominal bench height easy accessible by human operators, which is also substantially the height level for all the process modules so that the substrates can be conveniently loaded/unloaded by the substrate loader 340 moving along the rail structure 300. L2 is used to indicate a second height level of the substrate cart 350 in the in-line transfer structure 320. The second height level L2 is compatible with a substrate transfer line, which may be any height from the floor level to L3 level. In an embodiment, the substrate transfer line includes an incoming line at a lower height L2a and an outgoing line at a relative higher height L2b. The height difference of L2b-L2a may be substantially the same as the vertical dimension of the multi-level substrate cart 350 to act as an elevator for the convenience of transferring substrates between the substrate loader 340 and either the incoming or outgoing transfer line through the substrate cart 350.

Referring to FIG. 3 again, the system 3000 is a multi-module system having a plurality of process modules 310 disposed at the first height level L1 along the sides of the rail structure 300. In particular, each process module is a chamber configured to provide a vacuum environment via a pump module 318 coupled to a base member 317 of the chamber. The chamber also includes a lid cover member 313 and a gas mixer 315 coupled to several gas distributors 314 to supply a mixed work gas into the chamber through the lid cover member 313. As the mixed work gas is supplied, the substrates loaded onto a heater plate inside the chamber are heated to an elevated temperature. The heat energy would induce a chemical reaction involving the mixed work gas within the chamber to deposit a thin film onto the substrates in a predetermined process time.

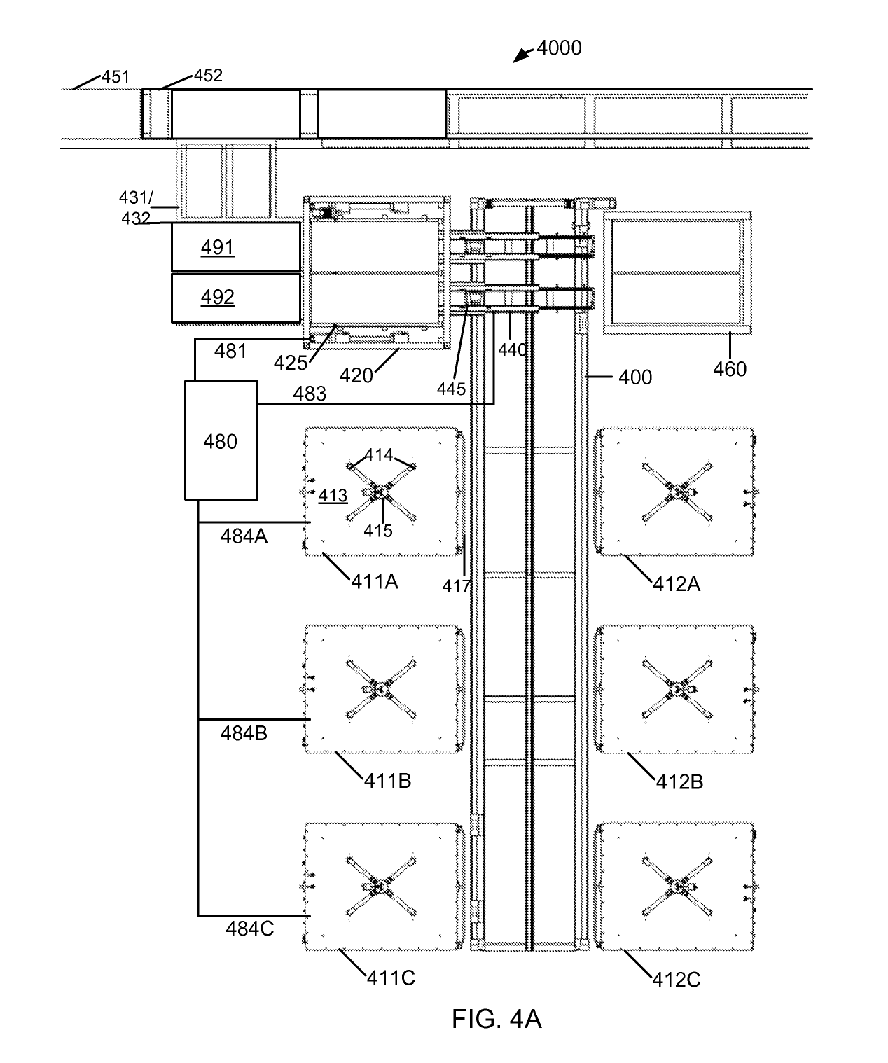

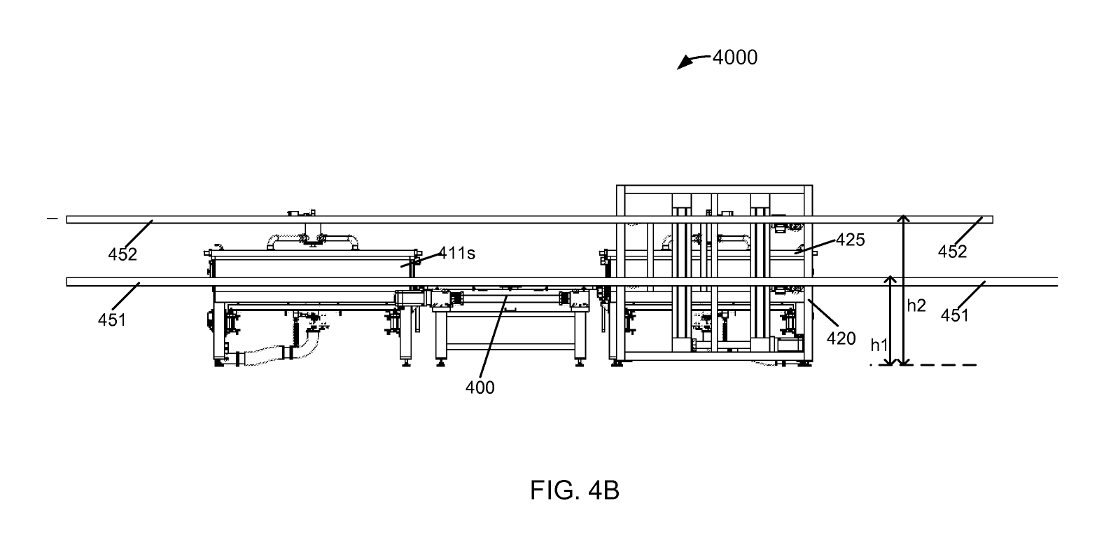

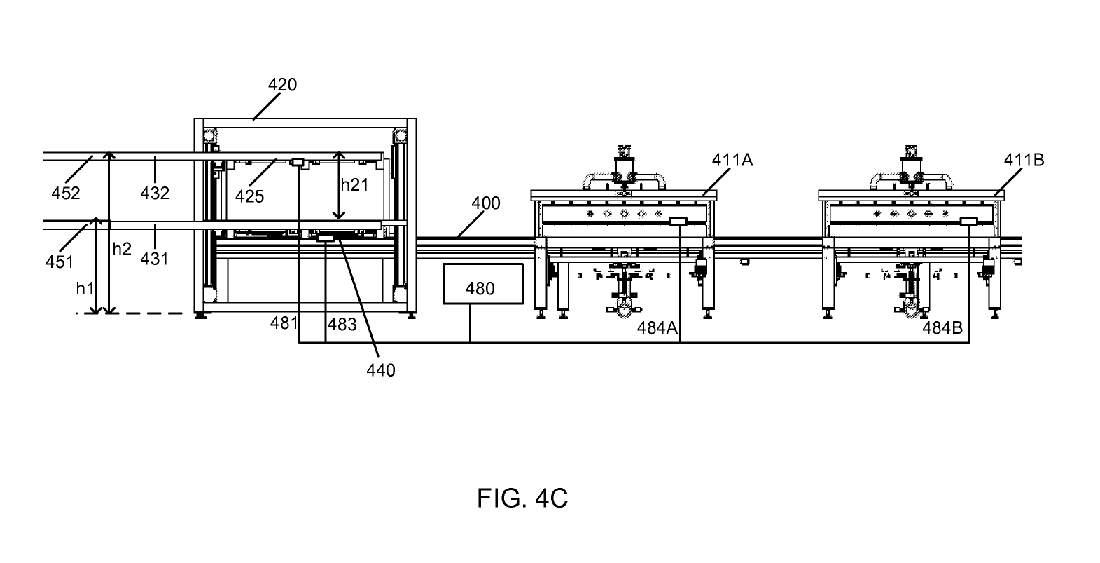

FIG. 4 is a top view of a multi-module system for processing thin-film photovoltaic devices according to another embodiment of the present invention. As shown, the multi-module system 4000 includes a plurality of thin-film process modules 411s (411A, 411B, 411C, . . . ) and 412s (412A, 412B, 412C, . . . ) respectively disposed along two long sides of a rail structure 400 for receiving a pair of substrates to process thin-film photovoltaic devices thereon. In a specific embodiment, the system 4000 includes a substrate transfer module 420 disposed next to the rail structure 400 and coupled to an incoming substrate transfer line 451 via a first connection device 431 and an outgoing substrate transfer line 452 via a second connection device 432. Therefore, a plurality of substrates delivered through the incoming transfer line 451 can be picked up by the substrate transfer module 420 via the first connection device 431. The substrate transfer module 420 also is configured to send substrates after processing back to the outgoing transfer line 452 via the second connection device 432. In a specific embodiment, the substrate transfer module 420 includes a substrate cart 425 for transferring one or more substrates in and out. For example in FIG. 4A, the substrate cart 425 is configured to hold a pair of substrates 491 and 492 (in rectangular shape) during a transfer time period. In another embodiment, the system 4000 includes a substrate loader 440 coupled to the rail structure 400 and configured to move along its length for loading one or more substrates from the substrate cart 425 to each of the plurality of process modules 411s and 412s and vice versa.

In a specific embodiment, FIG. 4A also shows some functional features of the process module 411A. In an implementation of the present invention, the process module is a vacuum chamber designed for thin-film deposition. In particular, the thin-film deposition chamber is configured to carry out a metal-organic chemical vapor deposition (MOCVD) to form an optical transparent conductive oxide layer over a pair of rectangular shaped substrates. Of course, other thin-film process may be implemented using similar in-line setup and module configuration. As shown in FIG. 4A, the process module (e.g., 411A) has a top lid cover member 413. The lid cover member 413 includes a gas mixing device 415 configured to receive predetermined work gases from several sources and form a mixed precursor gas for the MOCVD process. The mixed work gas is distributed into the chamber through four gas inlets 414 through the lid cover member 413. Also partially visible, each process module has a side door structure 417 available to open when the substrate loading/unloading is needed between a heater plate (not visible) disposed inside the chamber and the substrate loader 440 (moving along the rail structure 400). In a specific embodiment, within the system 4000 the substrates are transferred, loaded, unloaded, or returned all in a paired configuration in each of the substrate loader 440, process chamber 411s, and substrate cart 425 of the transfer module 420. In an embodiment, each of the plurality of process modules 411s is substantially the same as the process module 210 shown in FIG. 2 and process module 310 shown in FIG. 3.

FIG. 4B and FIG. 4C are side views of the FIG. 4A from different angles showing the multi-module system associated with two-level substrate transfer lines according to the embodiment of the present invention. As shown, the incoming substrate transfer line 451 is configured to be at a different height versus the outgoing substrate transfer line 452. The incoming transfer line 451 is set at a height level h1 substantially leveled with the substrate loader 440 on the rail structure 400. The outgoing transfer line 452 is set at a higher level h2. The transfer module 420 is configured to be an elevator rack wherein a substrate cart 425 is able to move up and down. The substrate cart 425 also is configured to have two support levels with a level-to-level distance substantially equal to the height difference h2−h1.

In an embodiment, the substrate cart 425 is in a first position with its lower support level aligned to the incoming transfer line 451 at h1 so that a substrate can be smoothly transferred from the incoming transfer line 451 into the substrate cart 425. In particular, as shown in FIG. 4A, two substrates 491 and 492 can be paired in a side-by-side configuration at the first connection device 431 before further being shifted to the lower support level of the substrate cart 425 in the transfer module 420. The pair of substrates then further can be transferred to the substrate loader 440 which is timely coordinated its travel and stop on the rail structure 400.

In another embodiment, the substrate cart 425 is configured to be a bi-level elevator moving up and down at two height levels within a rack structure of the transfer module 420. At a first height level, the lower support level of the substrate cart 425 is leveled with the incoming transfer line 451 and the substrate loader 440 and the higher support level is leveled with the outgoing transfer line 452. A pair of new substrates can be shifted to the lower support level of the substrate cart 425 from the incoming transfer line 451 via the first connection device 431, as seen both in FIG. 4A and in FIG. 4B. The substrate cart 425 then is able to move down to a second height level within the transfer module elevator rack 420 so that the higher support level of the substrate cart becomes leveled with the substrate loader 440. In a next predetermined schedule, the substrate loader 440 may pick up a pair of substrates after they are processed by one of the plurality of process modules 411s and move along the rail structure 400 to the position of the transfer module 420. Now, the pair of processed substrates can be shifted to the higher support level of the substrate cart 425 from the substrate loader 440. Next, the substrate cart 425 is controlled to move back up to the first height level so that the lower support level is leveled to the substrate loader 440 and the higher support level is leveled to the second connection device 432 that links to the outgoing transfer line 452. Subsequently, the pair of new substrates can be transferred to the substrate loader 440 and ready for being delivered to a process module (e.g., module 411A or 411B) while the pair of processed substrates being shifted and transferred to the outgoing transfer line 452, substantially at a same time.

Referring back to FIG. 4A, the multi-module system 4000 includes a controller 480 respectively coupled to the in-line substrate transfer module 420, the substrate loader 440, and each of the plurality of process modules 411s. The controller 480 is configured to manage a loading/unloading routine of the substrate loader 440 which travels and stops on the rail structure 400 based on a predetermined schedule including at least a predetermined process time and a consecutive time delay of operating each of the plurality of process modules 411s one after another. As shown, the controller 480 sends control signals or receives feedback signals via signal communication 481 to or from the substrate transfer module 420, via signal communication 483 to or from the substrate loader 440, and via signal communication 484 (i.e., respectively through lines 484A, 484B, 484C, . . . ) to or from each of the plurality of process modules 411s. In an embodiment, the signal communication can be wired or wireless. In another embodiment, the substrate loader, substrate transfer module, and each process module respectively is equipped with a corresponding drivers and sensors for process automation. For example, an elevator driver on the transfer module 420 is configured to receive control signal from the controller 480 to cause the substrate cart 425 moving up and down to a specific height level with a specific schedule. A motion driver on the rail structure 400 is configured to receive control signal from the controller 480 to cause the substrate loader traveling along the rail structure and stopping at a desired position in front of the transfer module 420 or in front of a particular process module as scheduled. An operation driver in each process module may control the operations such as substrate loading, chamber, pumping, gas filling, substrate heating, gas purging, and substrate unloading, or the likes. At the same time, a plurality of sensors (not explicitly shown) is placed in each of the system elements mentioned above to provide feedback signals to the controller 480. The sensors include timer, motion detector, temperature or pressure sensor or gauge, optical inspector, and more.

As shown in FIG. 4C, in a specific embodiment, the controller 480 sets an operation schedule for each of the plurality of process modules 411s to start a process sequentially with a predetermined time delay, and correspondingly within the predetermined time delay for the substrate cart 425 as a bi-level elevator to move up and down between a first height level and a second height level within he rack structure of the transfer module 420. Firstly within the predetermined time delay, the controller 480 sets the substrate cart 425 at the first height level. The first support level of the substrate cart 425 is leveled with the substrate loader 440 so that a first pair of substrates is transferred from its first support level thereof to the substrate loader 440. Further, the substrate loader 440 is controlled within the predetermined time delay to deliver to the first pair of substrates to a corresponding process module (e.g., 411A). The controller 480 also is configured for the substrate cart 425 within the predetermined time delay to load a second pair of substrates in the first support level and to move down to a second height level within the transfer module 420 so that the second support level of the substrate cart 425 is aligned with the first height level for receiving substrates from the substrate loader 440. In addition, the controller 480 is configured for the substrate loader 440 within the predetermined time delay to pick up a third pair of substrates after processed in another process module (e.g., 411B) and deliver back to the second support level of the substrate cart 425. Furthermore, the controller 480 drives the substrate cart 425 to move up to the first height level again so that the first support level is aligned to the substrate loader 440 and the second support level is aligned to the outgoing transfer line 452. Moreover, the controller 480 is configured to send control signal to the substrate cart 425 to transfer the second pair of substrates from the first support level of the substrate cart 425 to the substrate loader and at the same time transfer the third pair of substrates from the second support level of the substrate cart 425 to the outgoing transfer line 452. Of course, there can be many variations, alternatives, and modifications in the system operation and process control.

In an alternative embodiment, the system 4000 also includes a backup loading module 460 disposed next to the rail structure 400. In a specific embodiment, the backup loading module 460 is set at a position accessible by the substrate loader 440 on the rail structure. For example, in the FIG. 4A, the backup loading module 460 is set at an opposite side of the rail structure 400 relative to the substrate transfer module 420. The backup loading module 460 can be used for in-line substrate inspection or substrate replacement. If some substrates loaded from incoming transfer line are found to have defects in photovoltaic materials formed in previous process, the defective substrate can be taken away and added a replacement substrate from the backup loading module 460. The substrate after processed in one process module also can be selectively inspected at the backup loading module 460 before deliver it to the outgoing transfer line 452.

In another alternative embodiment, the multi-module system 1000 or 4000 disclosed throughout this specification is a scalable unit that can be duplicated and multiplied. For example, one or more duplicated systems 1000 or 4000 including a rail structure, a plurality of process modules along both sides of the rail structure, a transfer module next to an incoming substrate transfer line and an outgoing substrate transfer line, a substrate loader configured to move along the rail structure for transferring substrates between the transfer module and one of the plurality of process modules, can be disposed along the extended substrate transfer lines. It is understood that the examples and embodiments described herein are for illustrative purposes only and that various modifications or changes in light thereof will be suggest to persons skilled in the art and are to be included within the spirit and purview of this application and scope of the appended claims. Although the above has been generally described in terms of a plurality of process modules for MOCVD process and the corresponding process for fabricating thin film photovoltaic devices on paired substrates, other functional process modules and substrate configurations can also be used, without departing from the invention described by the claims herein.

What is claimed is:

1. A multi-module system for fabricating thin film photovoltaic devices, the system comprising:
a horizontal rail structure at a first height extending from a first end region to a second end region;
a first in-line transfer structure and a second in-line transfer structure respectively disposed at positions next to the first end region, the first in-line transfer structure being configured to supply and store a plurality of substrates to be processed and the second in-line transfer structure being configured to store and deliver the plurality of substrates after processing;
a plurality of process modules disposed substantially at the first height along the length of the rail structure;
a substrate loader coupled to the rail structure and configured to move from the first end region to the second end region along the rail structure and to load substrates to and unload substrates from the plurality of process modules, and to load substrates to the second in-line transfer structure; and
a controller coupled to the substrate loader, to each of the plurality of process modules, to the first in-line transfer structure and to the second in-line transfer structure for managing operation of each.

2. The system of claim 1 wherein each process module comprises a chamber having a side door structure facing the rail structure.

3. The system of claim 2 wherein each chamber comprises a top lid cover, at least four sides, and a bottom suspended by pressured air over four support members.

4. The system of claim 3 wherein each chamber has a gas inlet coupled to the top lid cover and a gas outlet through the bottom base coupled to a pump for providing a gaseous environment for performing chemical vapor deposition.

5. The system of claim 4 wherein each chamber includes a heater plate for supporting substrates disposed above the bottom base.

6. The system of claim 1 wherein the substrate loader comprises a robot arm capable of picking and releasing substrates from either side of the rail structure.

7. The system of claim 1 wherein the substrate loader is configured to load a pair of substrates horizontally side by side from the first in-line transfer structure and unload another pair of substrates to the second in-line transfer structure.

8. The system of claim 7 wherein each of the pair of substrates comprises a Copper Indium Diselenide base thin-film photovoltaic absorber material formed over a glass substrate having a rectangular shape.

9. The system of claim 1 wherein the first in-line transfer structure and the second in-line transfer structure are disposed side-by-side to each other at the first end region.

10. The system of claim 1 wherein the first in-line transfer structure and the second in-line transfer structure are disposed face-to-face on opposite sides of the rail structure near the first end region.

11. The system of claim 1 further comprising:
a maintenance station disposed at a position next to the second end region of the rail structure;
an incoming substrate transfer line and an outgoing substrate transfer line respectively coupled to the first in-line transfer structure and the second in-line transfer structure at a second height, the second height being above the first height; and
a crane disposed at a third height over all the plurality of process modules for transferring module parts from the process modules to the maintenance station, the third height being above the second height level.

12. The system of claim 11 wherein each of the first in-line transfer structure and the second in-line transfer structure comprise an elevator structure including a multi-level substrate cart for storing substrates.

13. The system of claim 12 wherein the multi-level substrate cart is configured to move up and down to receive and deliver substrates.

14. The system of claim 12 wherein the multi-level substrate cart is configured to move up and down to transfer substrates to and from the first height.

15. The system of claim 12 wherein the controller comprises a computer with a plurality of commands pre-loaded via a user interface and executed through a plurality of sensors coupled to the substrate loader, the multi-level substrate cart, and the process modules.

16. The system of claim 15 wherein the controller sets an operation schedule for the process modules to start a process sequentially with a predetermined time delay and within the predetermined time delay obtains a pair of substrates from the first in-line transfer structure, delivers the substrates to a process module, picks up a different pair of substrates processed in another process module, and to deliver those substrates to the second in-line transfer structure.

17. A system for in-line processing a plurality of thin film photovoltaic devices, the system comprising:
a horizontal rail structure disposed at a first height;
an in-line substrate transfer module disposed next to the horizontal rail structure, the in-line substrate transfer module coupled to an incoming transfer line at the first height for receiving substrates ready for processing, and coupled to an outgoing transfer line at a second height for delivering substrates after processing;
a plurality of process modules disposed substantially at the first height along the length of the rail structure;
a substrate loader configured to move along the rail structure for transferring substrates from the in-line substrate transfer module to the process modules and for picking up the substrates after processing and returning them to the in-line substrate transfer module; and
a controller coupled to the substrate loader, each of the plurality of process modules, and the in-line substrate transfer module, the controller managing handling of the substrates.

18. The system of claim 17 wherein the in-line substrate transfer module comprises an elevator configured to move up and down between the first height and the second height.
